(19) United States
(12) Patent Application Publication
(10) Pub. No.: US 2024/0268132 A1
(43) Pub. Date: Aug. 8, 2024

(54) LEGGED SUPPORT STRUCTURE TO MITIGATE STACKED DIE OVERHANG DEFLECTION

(71) Applicant: Micron Technology, Inc., Boise, ID (US)

(72) Inventors: See Hiong LEOW, Singapore (SG); Hong Wan NG, Singapore (SG); Chin Hui CHONG, Singapore (SG); Ling PAN, Singapore (SG); Kelvin Aik Boo TAN, Singapore (SG); Seng Kim YE, Singapore (SG)

(21) Appl. No.: 18/404,657

(22) Filed: Jan. 4, 2024

Related U.S. Application Data
(60) Provisional application No. 63/482,944, filed on Feb. 2, 2023.

(51) Int. Cl. H10B 80/00; H01L 25/00; H01L 25/065; H01L 25/18

(52) U.S. Cl. CPC H10B 80/00; H01L 25/0652; H01L 25/18; H01L 25/50; H01L 2225/06517; H01L 2225/06562; H01L 2225/06586; H01L 2225/06589

(57) ABSTRACT

Some implementations described herein are directed to a semiconductor die package including a stacked die arrangement. The semiconductor die package includes one or more legged support structures between respective overhang portions of the stacked die arrangement and a substrate of the semiconductor die package. The one or more legged support structures may reduce a likelihood of the respective overhang portions deflecting during manufacturing of the semiconductor die package. By reducing the likelihood of the overhang portions deflecting, a quality and reliability of the semiconductor die package may be improved.

### CROSS-REFERENCE TO RELATED APPLICATION

This Patent Application claims priority to U.S. Provisional Patent Application No. 63/482,944, filed on Feb. 2, 2023, entitled “LEGGED SUPPORT STRUCTURE TO MITIGATE STACKED DIE OVERHANG DEFLECTION,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a legged support structure to mitigate stacked die overhand deflection.

### BACKGROUND

A semiconductor die package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor die package may be referred to as a semiconductor chip package that includes one or more ICs. A semiconductor die package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor die package, multiple semiconductor die packages, and/or one or more components of a semiconductor die package (e.g., one or more semiconductor devices with or without a casing).

An electronic system assembly may include multiple semiconductor die packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor die packages and other system components of the electronic system assembly. Accordingly, the multiple semiconductor die packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIGS. 1A and 1B are diagrams of an example apparatus that may be manufactured using techniques described herein.

FIG. 2 is a diagram of an example memory device that may be manufactured using techniques described herein.

FIG. 3 is a diagram of an example implementation of the legged support structure.

FIG. 4 is a diagram of an example implementation of the legged support structure.

FIG. 5 is a diagram of an example implementation of the legged support structure.

FIG. 6 is a diagram of an example implementation of multiple implementations the legged support structure.

FIG. 7 is a diagram of an example implementation of the legged support structure.

FIGS. 8A-8E describe an example series of operations that may be used to form a legged support structure to mitigate stacked die overhang deflection.

FIG. 9 is a flowchart of an example method associated with legged support structure to mitigate stacked die overhang deflection.

FIG. 10 is a flowchart of an example method associated a with legged support structure to mitigate stacked die overhang deflection.

FIG. 11 is a flowchart of an example method associated a with legged support structure to mitigate stacked die overhang deflection.

### DETAILED DESCRIPTION

A semiconductor die package may include multiple semiconductor dies in a stacked arrangement to reduce a footprint of the dies. Within the stacked arrangement, one or more of the multiple semiconductor dies may include overhang portions that extends beyond edges of underlying semiconductor dies. During a molding operation that encapsulates the multiple semiconductor dies, pressure and/or forces may cause deflections to ends of one or more of the overhang portions. These deflections may cause quality and reliability issues within the semiconductor die package. Such quality and reliability issues may include die cracking or cosmetic defects, among other examples.

As a result of the quality and reliability issues, a manufacturing yield of the semiconductor die package may be decreased. Additionally, or alternatively and due to the quality and reliability issues, a field failure rate of the semiconductor die package may be increased. To overcome the reduction in the manufacturing yield and/or the increase in the field failure rate, an increase in resources (e.g., semiconductor manufacturing tools, manpower, computing resources, and/or raw materials) may be required to support a market that consumes a volume of the semiconductor die package.

Some implementations described herein are directed to a semiconductor die package including a stacked die arrangement. The semiconductor die package includes one or more legged support structures between respective overhang portions of the stacked die arrangement and a substrate of the semiconductor die package. The one or more legged support structures may reduce a likelihood of the respective overhang portions deflecting during manufacturing of the semiconductor die package. By reducing the likelihood of the overhang portions deflecting, a quality and reliability of the semiconductor die package may be increased relative to a quality and reliability of another semiconductor die package (e.g., including another stacked die arrangement) not including the legged support structures.

In this way, an amount of resources (e.g., semiconductor manufacturing tools, manpower, computing resources, and/or raw materials) needed to support a market of the semiconductor die package may be decreased. Such resources may accordingly, be reallocated to other semiconductor die package manufacturing needs.

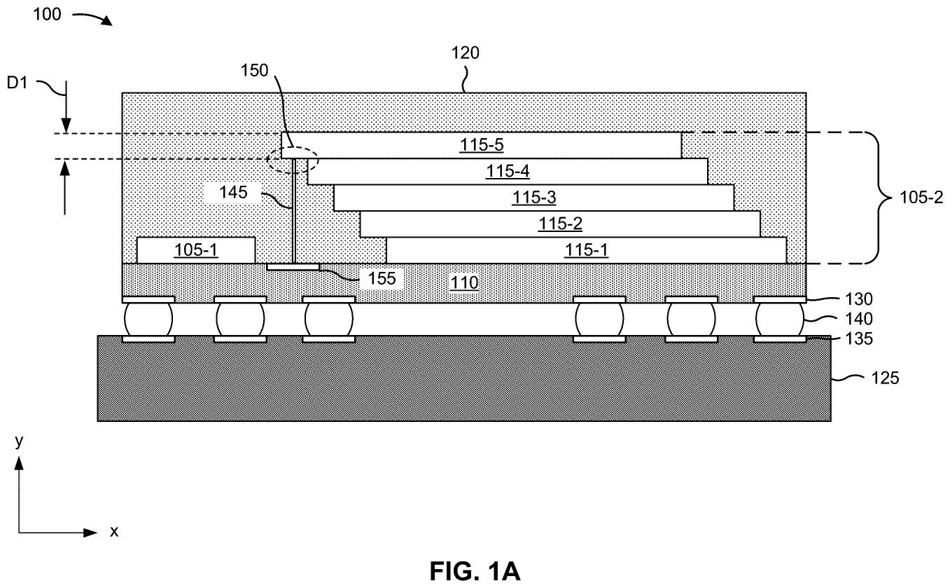

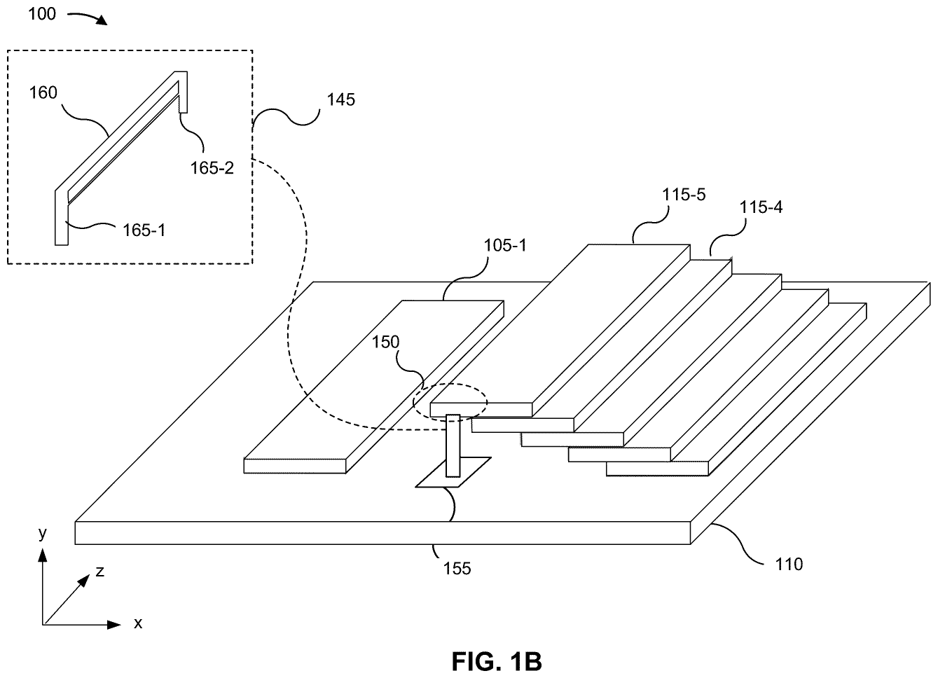

FIGS. 1A and 1B are diagrams of an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor die package, an assembly, a semiconductor device assembly, or an integrated assembly.

As shown in FIG. 1A (e.g., a side view of the apparatus 100), the apparatus 100 may include one or more integrated circuits 105, shown as a first integrated circuit 105-1 and a second integrated circuit 105-2, disposed on a substrate 110. An integrated circuit 105 may include any type of circuit, such as an analog circuit, a digital circuit, a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include a single semiconductor die 115 (sometimes called a die), as shown by the first integrated circuit 105-1. In some implementations, an integrated circuit 105 may include multiple semiconductor dies 115 (sometimes called dies), as shown by the second integrated circuit 105-2, which is shown as including five semiconductor dies 115-1 through 115-5.

As shown in FIG. 1A, for an integrated circuit 105 that includes multiple dies 115, the dies 115 may be stacked on top of each other to reduce a footprint of the apparatus 100. In some implementations, a spacer may be present between dies 115 that are proximate to one another in the stack to enable electrical separation and heat dissipation. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on. Although FIG. 1A shows the dies 115 stacked in a shingle stack (e.g., with die edges that are not aligned, which provides space for wire bonding near the edges of the dies 115), in some implementations, the dies 115 may be stacked in a different arrangement, such as a straight stack (e.g., with aligned die edges).

In some implementations, a thickness D1 of each of the dies 115 may be included in a range of approximately 40 microns to approximately 50 microns. If the thickness D1 is less than approximately 40 microns, a robustness of the dies 115 may be insufficient to withstand manufacturing operations (e.g., assembly operations) used to form the apparatus 100. If the thickness D1 is greater than approximately 50 microns, an overall thickness of the apparatus 100 may not satisfy a thickness threshold necessary for an end use (e.g., a field use) of the apparatus 100. However, other values and ranges for the thickness D1 are within the scope of the present disclosure.

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a mold compound, a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system.

FIG. 1A further shows an example legged support structure 145. The legged support structure 145 is between an overhang portion 150 (e.g., of the semiconductor die 115-5) and a pad structure 155. In some implementations, the legged support structure 145 corresponds to a wire bond loop formed by a semiconductor processing tool (e.g., a wire bonding tool). As described in greater detail in connection with FIGS. 1B-11, and elsewhere herein, the apparatus 100 may include multiple implementations of the legged support structure 145 to mitigate stacked die overhang deflection.

FIG. 1B (e.g., an isometric view of a portion of the apparatus 100) shows additional details of the legged support structure 145. As shown in FIG. 1B, the legged support structure 145 includes an approximately horizontal span 160, a leg 165-1, and a leg 165-2. The approximately horizontal span 160 may traverse a path that is approximately parallel an edge of the die 115-4 and directly below the overhang portion 150. Additionally, or alternatively, the leg 165-1 (and/or the leg 165-2) may be bonded a pad structure 155 on the substrate 110. In some implementations, a bond to the pad structure may be formed through a wire bonding operation (e.g., a solid phase welding operation).

As described in connection with FIGS. 1A, 1B, and elsewhere herein, a semiconductor device assembly (e.g., the apparatus 100 of FIG. 1A) includes a substrate (e.g., the substrate 110 of FIG. 1A). The semiconductor device assembly includes a first semiconductor die (e.g., the die 115-4 of FIG. 1A) above the substrate that includes an edge. The semiconductor device assembly includes a second semiconductor die (e.g., the die 115-5 of FIG. 1A) in a stacked arrangement above the first semiconductor die. The second semiconductor die include an overhang portion (e.g., the overhang portion 150 of FIG. 1A) extending beyond the edge. The semiconductor device assembly further includes a legged support structure (e.g., the legged support structure 145 of FIG. 1A) between the overhang portion and the substrate. The legged support structure includes an approximately horizontal span (e.g., the approximately horizontal span 160 of FIG. 1B) traversing a path that is approximately parallel to the edge and directly below the overhang portion.

The legged support structure 145 may reduce a likelihood of the overhang portion 150 deflecting during manufacturing of the semiconductor device assembly (e.g. during a molding operation that encapsulates the integrated circuits 105-1 and 105-2 of apparatus 100). By reducing the likelihood of the overhang portion 150 deflecting, a likelihood a quality and/or reliability defect (e.g., cracking of the semiconductor die 115-5 and/or a visual blemish of the semiconductor device assembly) may be reduced.

As indicated above, FIGS. 1A and 1B are provided as an example. Other examples may differ from what is described with regard to FIGS. 1A and 1B.

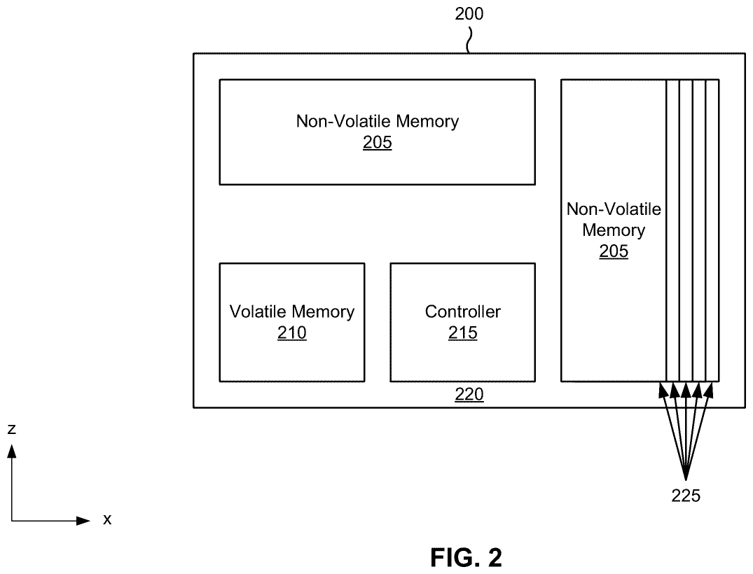

FIG. 2 is a diagram of an example memory device 200 that may be manufactured using techniques described herein. The memory device 200 is an example of the apparatus 100 described above in connection with FIG. 1. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes a single die. Additionally, or alternatively, the non-volatile memory 205 may include multiple dies, such as stacked semiconductor dies 225 (e.g., in a straight stack, a shingle stack, or another type of stack), as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

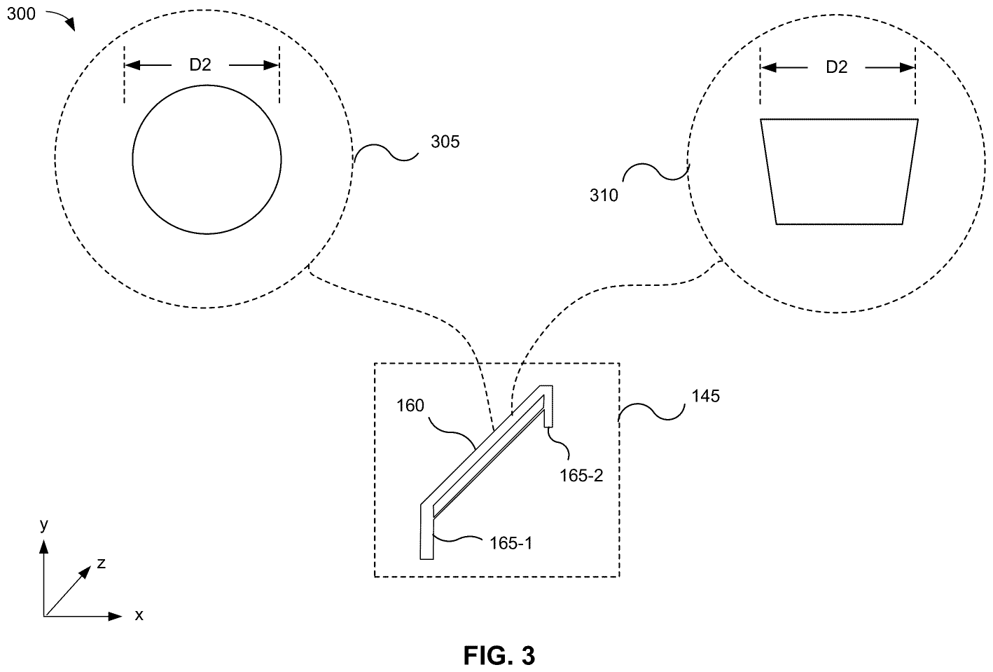

FIG. 3 is a diagram of an example implementation 300 of the legged support structure 145. The legged support structure 145 may include one or more properties (e.g., dimensions and/or mechanical properties) suitable for supporting (e.g., mitigating deflection of) one or more overhang portions (e.g., one or more instances of the overhang portion 150) of one or more dies (e.g., one or more of the dies 115) during formation of a semiconductor die package (e.g., the apparatus 100).

As shown in the isometric view of FIG. 3, a cross section of the legged support structure 145 may include one or more shapes. For example, a cross section of the legged support structure 145 may include an approximately circular shape 305. Additionally, or alternatively, a cross section of the legged support structure 145 may include at least one curved edge.

In some implementations, a cross section of the legged support structure 145 includes an approximately trapezoidal shape 310. In such implementations, the approximately trapezoidal shape 310 may increase a moment of inertia of the legged support structure 145 to improve a mechanical robustness and/or a rigidity of the legged support structure 145. Additionally, or alternatively, a cross section of the legged support structure 145 may include at least on approximately linear edge.

In some implementations, a width D2 of the legged support structure 145 is included in a range of approximately 30 microns to approximately 38 microns. If the width D2 is less than approximately 30 microns, and based on a cross sectional shape of the legged support structure 145, a moment of inertia of the legged support structure 145 may be insufficient to withstand a load (e.g., a bending moment) causing deflection to one or more dies (e.g., the dies 115). If the width D2 is greater than approximately 38 microns, and based on a cross section of the legged support structure 145, consumption of materials may increase to add to a manufacturing cost of the legged support structure 145. However, other values and ranges for the width D2 of the legged support structured 145 are within the scope of the present disclosure.

The legged support structure 145 may include materials having one or more mechanical properties that are conducive to mitigating deflection of one or more dies (e.g., the dies 115) and/or conducive to forming of the legged support structure 145. For example, the legged support structure 145 may include a material may having a modulus of elasticity that is included in a range of approximately 115 gigapascals (GPa) to approximately 130 GPa. If the modulus of elasticity is less than approximately 115 GPa, a rigidity of the legged support structure 145 may be insufficient to support the overhang portion 150 during a molding operation. If the modulus of elasticity is greater than approximately 130 GPa, an operation used to form the legged support structure 145 (e.g., a wire bonding operation) may be impeded (e.g., slowed) and create manufacturing inefficiencies. However, other values and ranges for the modulus of elasticity of the material are within the scope of the present disclosure.

Additionally, or alternatively, the legged support structure 145 may include a material having one or more properties suitable for a wire bonding operation that forms the legged support structure 145. For example, a tensile strength of the material may be included in a range of approximately 200 megapascals (MPa) to approximately 380 MPa. If the tensile strength is less than approximately 200 mPa, the legged support structure 145 may rupture during formation. If the tensile strength is greater than approximately 380 MPa, an operation used to form the legged support structure 145 (e.g., a wire bonding operation) may be impeded (e.g., a tool throughput may be slowed) and create manufacturing inefficiencies. However, other values and ranges for the tensile strength of the material are within the scope of the present disclosure.

Additionally, or alternatively, an elongation at break property of the material may be included in a range of approximately 10% to approximately 20%. If the elongation at break property is less than approximately 10%, the legged support structure 145 may rupture during formation. If the elongation at break property is greater than approximately 20%, a profile of the legged support structure 145 may not hold form during an operation used to form a semiconductor die package including the legged support structure 145 (e.g., a molding operation used to form the apparatus 100). However, other values and ranges for the elongation at break property of the material included in the legged support structure 145 are within the scope of the present disclosure.

In some implementations, structure 145 may include a ductile cable (e.g., a bond wire). Additionally, or alternatively, the legged support structure 145 may include a copper material. Additionally, or alternatively, the legged support structure 145 may include a gold material, a silver material, a palladium material, or an aluminum material.

As indicated above, FIG. 3 is provided as an example. Other examples may differ from what is described with regard to FIG. 3.

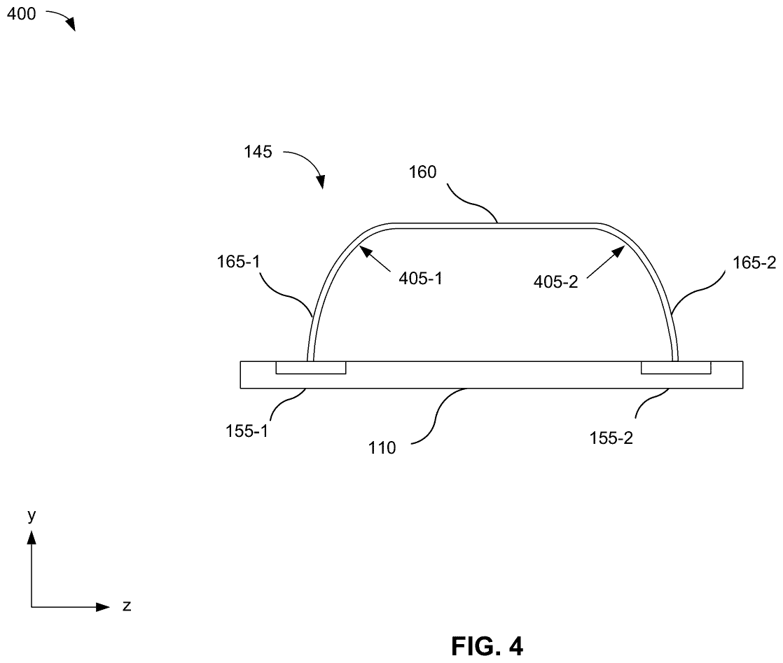

FIG. 4 is a diagram of an example implementation 400 of the legged support structure 145. In the side view of FIG. 4, the legged support structure 145 include a radially curved portion 405-1 and a radially curved portion 405-2. In some implementations, respective radii of curvature of the radially curved portions 405-1 and 405-2 are approximately the same. In some implementations, the respective radii of curvature of the radially curved portions 405-1 and 405-2 are different. In some implementations, the radially curved portion 405-1 and 405-2 provide stress relief (e.g., avoid stress concentrations) at transitions between the approximately horizontal span 160 and the leg 165-1 and/or the leg 165-2. In some implementations, profiles and or radii of the radially curved portions 405-1 and 405-2 may be based on a recipe used by a tool used to form the legged support structure 145 (e.g., a wire loop recipe used by a wire bond tool to form the legged support structure 145).

As shown in FIG. 4, the leg 165-1 may extend from the radially curved portion 405-1 to the pad structure 155-1 on the substrate 110. As further shown in FIG. 4, the leg 165-2 may extend from the radially curved portion 405-2 to the pad structure 155-2 on the substrate 110.

As described in connection with FIGS. 1A-4, and elsewhere herein, a semiconductor device assembly (e.g., the apparatus 100 of FIG. 1A) includes a substrate (e.g., the substrate 110 of FIG. 1A). The semiconductor device assembly includes a first semiconductor die (e.g., the die 115-4 of FIG. 1A) above the substrate. The semiconductor device assembly includes a second semiconductor die (e.g., the die 115-5 of FIG. 1A) in a stacked arrangement above the first semiconductor die. The second semiconductor die includes an overhang portion (e.g., the overhang portion 150 of FIG. 1A) extending beyond the edge. The semiconductor device assembly includes a legged support structure (e.g., the legged support structure 145 of FIG. 1A) between the overhang portion and the substrate. The legged support structure has a profile including an approximately horizontal span (e.g., the approximately horizontal span 160 of FIG. 4) directly below the overhang portion. The legged support structure further includes radially curved portions (e.g., the radially curved portions 405-1 and 405-2 of FIG. 4) at opposing ends of the approximately horizontal span.

As indicated above, FIG. 4 is provided as an example. Other examples may differ from what is described with regard to FIG. 4.

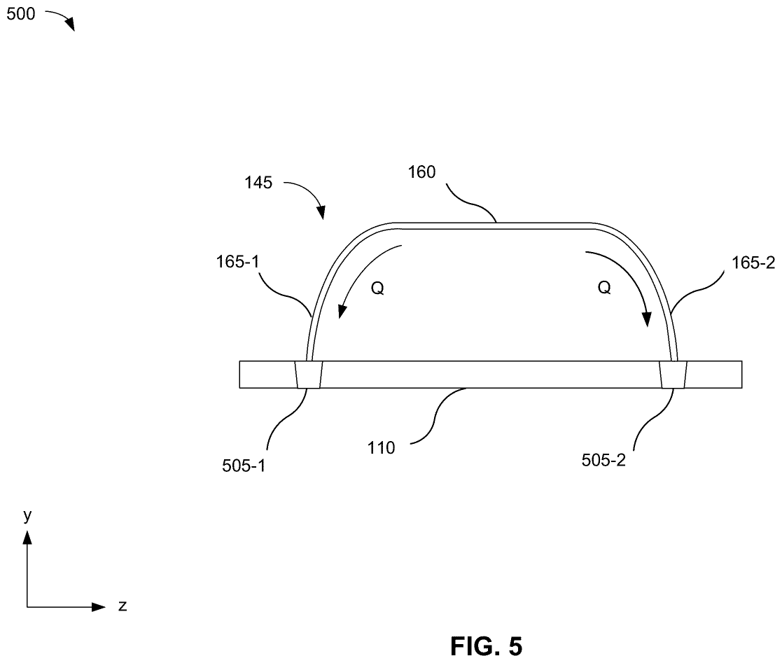

FIG. 5 is a diagram of an example implementation 500 of the legged support structure 145. In the side view of FIG. 5, the leg 165-1 is connected to a thermal vertical interconnect access (via) structure 505-1. Additionally, or alternatively and as shown in FIG. 5, the leg 165-2 is connected to the thermal via structure 505-2. The connections, sometimes referred to as thermal contact, provide paths for heat transfer (e.g., “Q” in watts) from the legged support structure 145 to the thermal via structure 505-1 and/or 505-2.

In some implementations, the thermal via structure 505-1 and/or 505-2 include a material with relatively high thermal conductivity (e.g., a copper material, an aluminum material). In some implementations, the thermal via structures 505-1 and/or 505-2 may include portions of a pad structure (e.g., the pad structure 155). In some implementations, the thermal via structure 505-1 and/or 505-2 further connect to additional structures and/or features (e.g., solder balls, heat sinks) to transfer the heat away from the thermal via structure 505-1 and/or 505-2 for dissipation.

In some implementations, the legged support structure 145 in contact with the thermal via structure 505-1 and/or 505-2 may transfer heat at a rate that enables a junction temperature of a die above the legged support structure 145 (e.g., the die 115-5) satisfies a threshold. In such cases, an electrical performance of the die (e.g., a signaling speed) may increase relative to another die not satisfying the threshold. Additionally, or alternatively and in such a case, a useful life of the die may extend relative to the other die.

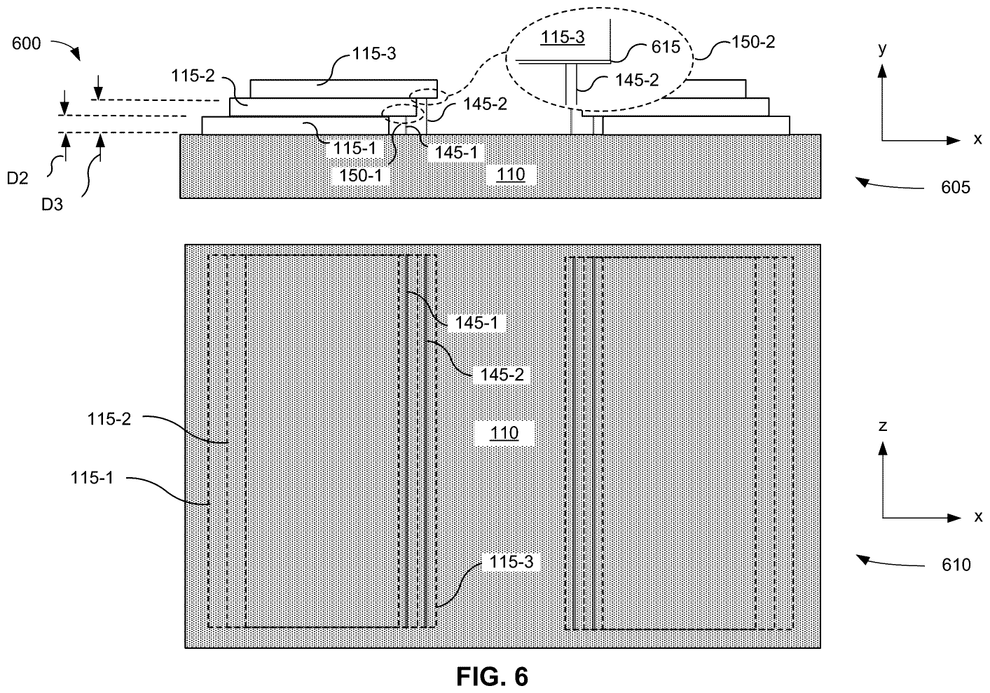

FIG. 6 is a diagram of an example implementation 600 of multiple implementations of the legged support structure 145. FIG. 6. includes an example side view 605 of a portion of an apparatus (e.g., the apparatus 100) and a top view 610 (e.g., a plan view) of the portion of the apparatus.

As shown in FIG. 6, a stacked arrangement includes dies 115-1, 115-2, and 115-3. The legged support structure 145-1 (e.g., a first legged support structure) supports the overhang portion 150-1 (e.g., a first overhang portion) of the die 115-2. Further, and as shown in FIG. 6, the legged support structure 145-2 (e.g., a second legged support structure) supports the overhang portion 150-2 (e.g., a second overhang portion) of the die 115-3.

As shown in FIG. 6, the legged support structure 145-1 has a height D2. Additionally, or alternatively and as shown in FIG. 6, the legged support structure 145-2 has a height D3. As shown in FIG. 6, the height D3 is greater relative to the height D2.

In some implementations, and as shown in the magnified view of 150-2, an adhesive layer 615 (e.g., a die attach film) may be on an underside surface of one or more overhang portions. In some implementations, the adhesive layer 615 is in contact with one or more portions of a legged support structure (the approximately horizontal span of the legged support structure 145-2, among other examples). Further, and in some implementations, the adhesive layer 615 includes one or more compliant properties.

As shown in FIG. 6, support regions may be directly below, and traverse along, the overhang portions 150-1 and 150-2. For example, a support region provided by the legged support structure 145-1 may traverse a path that is approximately parallel to an edge of the die 115-1. Additionally, or alternatively, a support region provided by the legged support structure 145-2 may traverse a path that is approximately parallel to an edge of the die 115-2.

As indicated above, FIG. 6 is provided as an example. Other examples may differ from what is described with regard to FIG. 6.

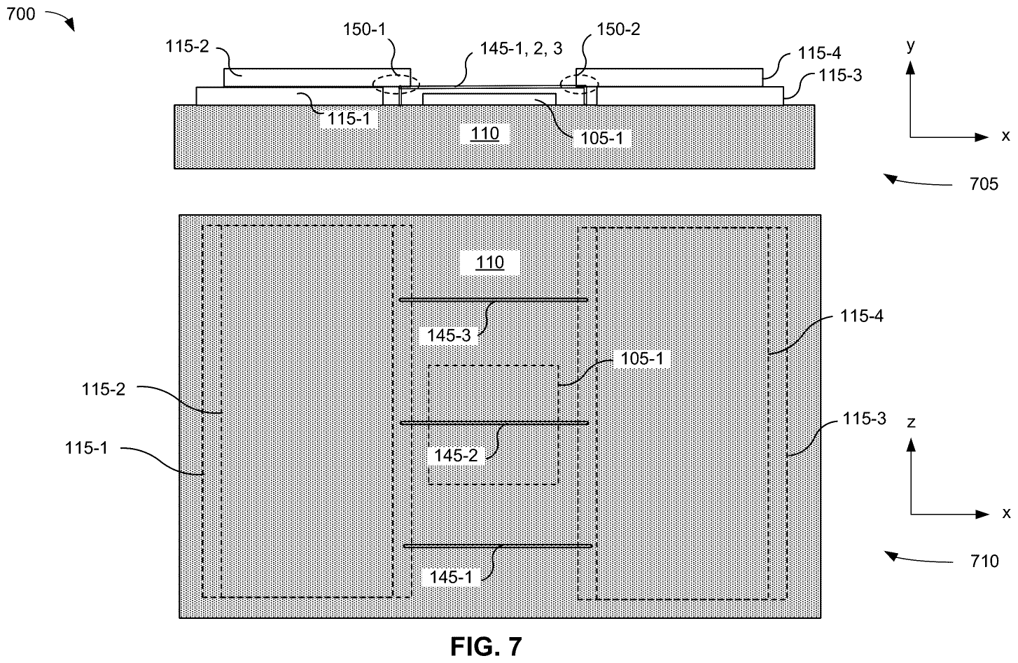

FIG. 7 is a diagram of an example implementation 700 of the legged support structure 145. FIG. 7. includes an example side view 705 of a portion of an apparatus (e.g., the apparatus 100) and a top view 710 (e.g., a plan view) of the portion of the apparatus.

As shown in FIG. 7, a stacked arrangement includes dies 115-1 and 115-2. The stacked arrangement including the dies 115-1 and 115-2 (e.g., a first stacked arrangement) includes the overhang portion 160-1.

Further, and as shown in FIG. 7, a stacked arrangement includes dies 115-3 and 115-4. The stacked arrangement including the dies 115-3 and 115-4 (e.g., a second stacked arrangement) includes the overhang portion 160-2.

In some implementations, and as shown in FIG. 7, legged support structures 145-1, 145-2, and 145-3 are “shared” between the overhang portions 160-1 and 160-2. In other words, the legged support structures 145-1, 145-2, and 145-3 are not dedicated to traversing along overhang portions of dies of the stacked arrangements. In contrast to being parallel to edges of the dies 115-1 and 115-2, the legged support structure 145-1, 145-2, and 145-3 are approximately orthogonal to the edges of the dies. In such a case, support regions may be above respective legs of the of the legged support structures 145-1, 145-2, and 145-3.

Further, and as shown in FIG. 7, the integrated circuit 105-1 (e.g., a semiconductor die) may be below the legged support structure 145-2. The integrated circuit 105-1, which may correspond to a controller device, may be below the legged support structure 145-2 to conserve space in the apparatus.

As described in connection with FIGS. 1A-7, and elsewhere herein, a semiconductor device assembly (e.g., the apparatus 100) includes a substrate (e.g., the substrate 110). The semiconductor device assembly a first semiconductor die (e.g., the die 115-2 of FIG. 7), in a first stack of dies (e.g., the dies 115-1 and 115-2 of FIG. 7), above the substrate that includes a first edge. The semiconductor device assembly includes second semiconductor die (e.g., the die 115-3 of FIG. 7), in a second stack of dies (e.g., the dies 115-3 and 115-4 of FIG. 7), above the substrate, proximate to the first semiconductor die, that includes a second edge that is approximately parallel the first edge and separated from the first edge. The semiconductor device assembly includes a third semiconductor die (e.g., the die 115-2) in a stacked arrangement above the first semiconductor die in the first stack of dies that includes a first overhang portion (e.g., the overhang portion 150-1 of FIG. 7) extending beyond the first edge. The semiconductor device assembly includes a fourth semiconductor die (e.g., the die 115-4 of FIG. 7) in a stacked arrangement above the second semiconductor die in the second stack of dies that includes a second overhang portion (e.g., the overhang portion 150-2 of FIG. 7) extending beyond the second edge. The semiconductor device assembly includes legged support structure (e.g., the legged support structure 145-2 of FIG. 7) between the first semiconductor die and the second semiconductor die. The legged support structure includes a first portion directly under the first overhang portion that is configured to support the first overhang portion and a second portion directly under the second overhang portion that is configured to support the second overhang portion.

As indicated above, FIG. 7 is provided as an example. Other examples may differ from what is described with regard to FIG. 7.

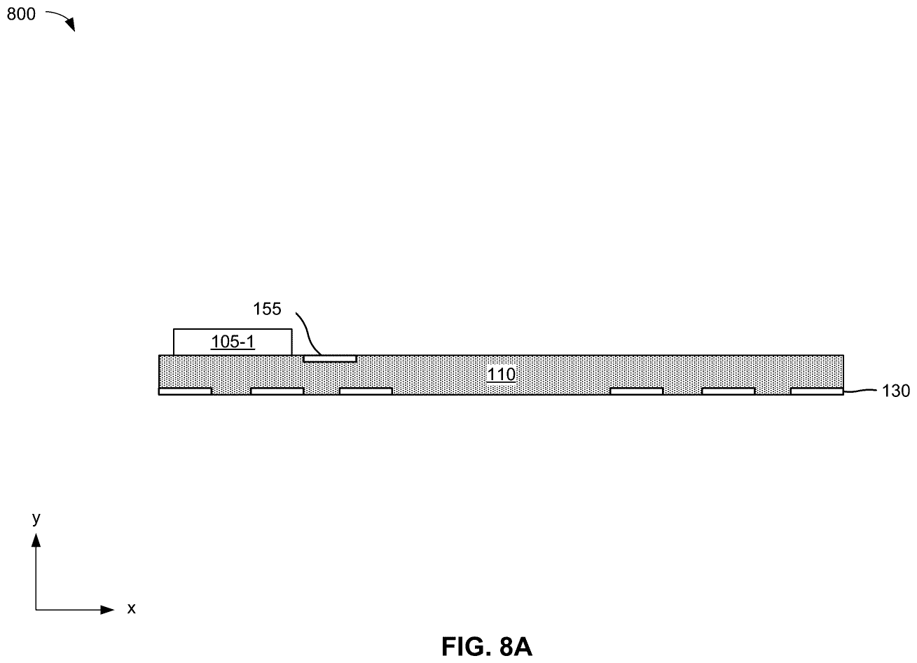

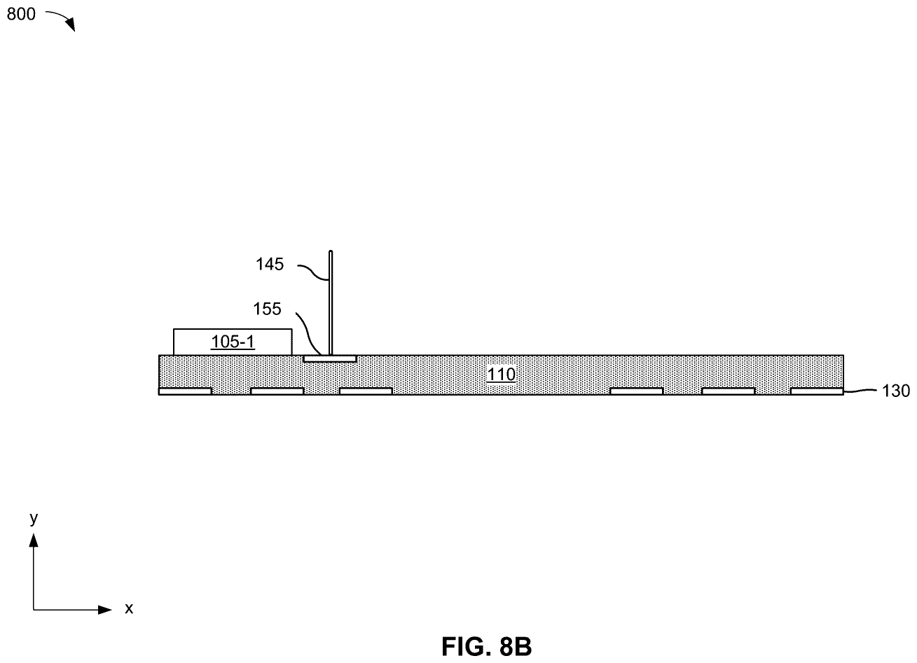

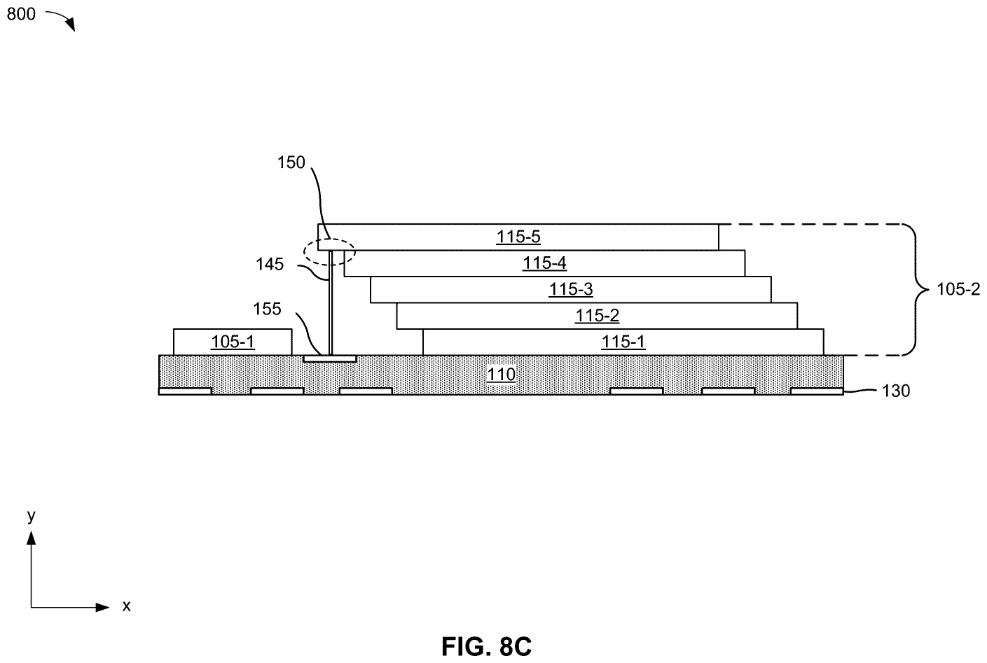

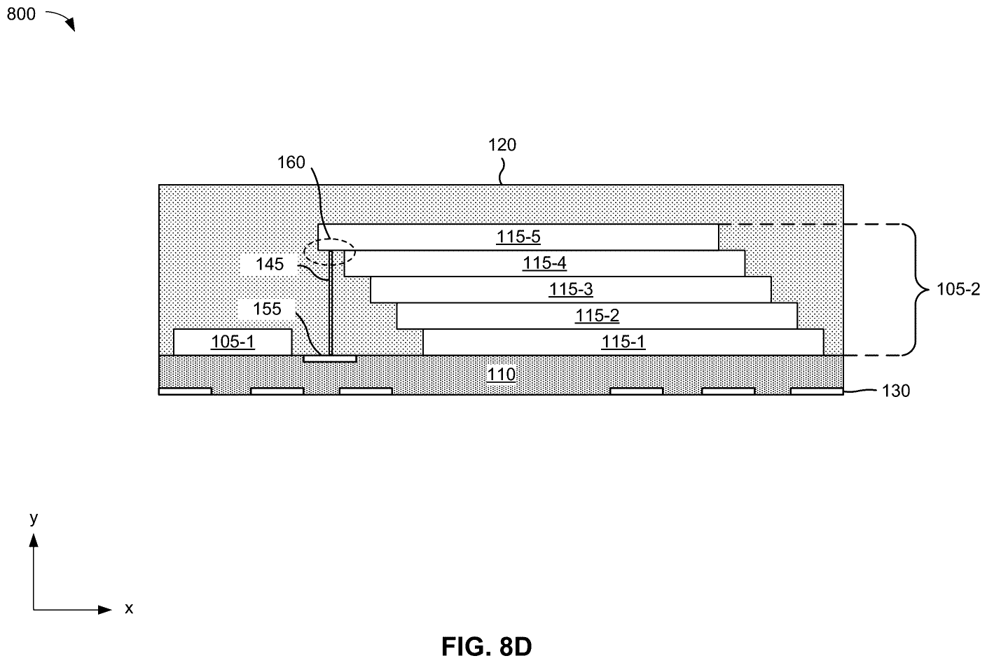

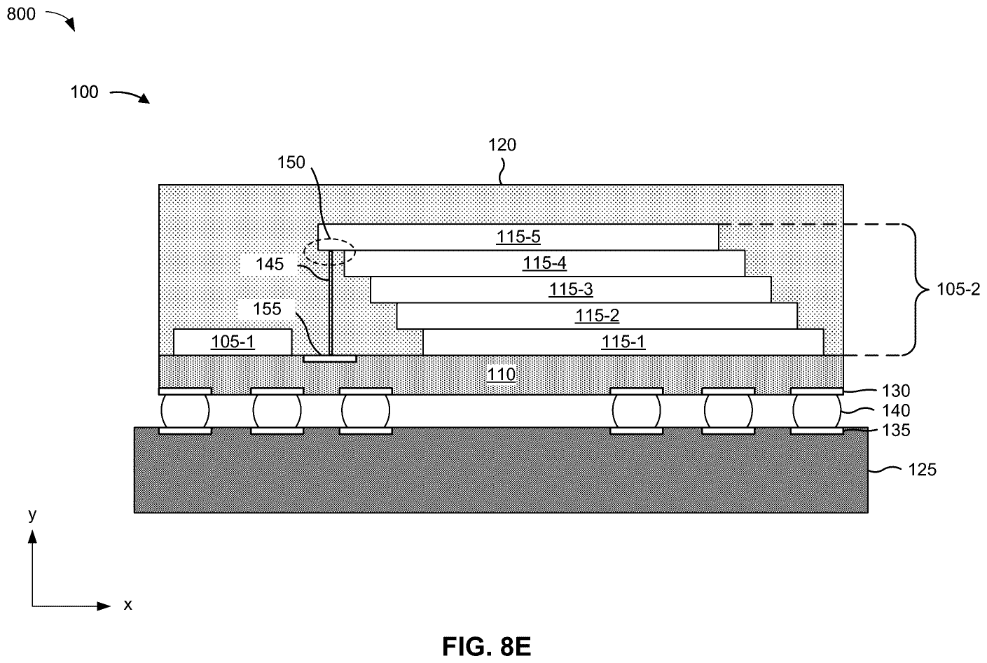

FIGS. 8A-8E describe an example series of operations 800 that may be used to form a legged support structure to mitigate stacked die overhang deflection. In some implementations, the series of operations 800 may be performed using one or more semiconductor processing tools located in semiconductor facility and configured to assemble semiconductor device packages and/or assemblies. As shown in FIG. 8A, the series of operations includes placing the integrated circuit 105-1 on the substrate 110.

As shown in FIG. 8B, the series of operations 800 includes forming the legged support structure 145. For example, and in some implementations, a wire bond tool forms the legged support structure 145. As shown in FIG. 8B, the wire bond tool may bond a leg of the legged support structure 145 (e.g., the leg 165-1 or the leg 165-2 of FIG. 1B) to the pad structure 155.

As shown in FIG. 8C, the series of operation includes forming the integrated circuit 105-2 (e.g., the stacked die arrangement including the dies 115-1 through 115-5) over the substrate 110. For example, and in some implementations, a die attach tool forms the integrated circuit 105-2 over the substrate 110. As shown in FIG. 8C, the die attach tool may place the die 115-5 such that the overhang portion is over the legged support structure 145.

As shown in FIG. 8D, the integrated circuit 105-1, the integrated circuit 105-2, and the legged support structure 145 are encapsulated with a casing 120. For example, and in some implementations, a molding tool may encapsulate the integrated circuit 105-1, the integrated circuit 105-2, and the legged support structure 145 with a mold compound. During the encapsulation, the legged support structure 145 may mitigate a deflection of the die 115-5.

As shown in FIG. 8E, the circuit board 125 and the substrate 110 are connected to form the apparatus 100. As an example, and in some implementations, a pick and place tool may co-locate the circuit board 125 (including the solder balls 140) and the substrate. A reflow tool may then reflow the solder balls 140 connect the circuit board 125 and the substrate 110 to form the apparatus 100.

In some implementations, a sequence of operations related to placing the dies 115-1 through 115-5 and forming the legged support structure 145 may vary. For example, and in the context of FIGS. 8A-8E, a sequence may include placing the die 115-1 through 115-4, forming the legged support structure 145, and then placing the die 115-5. As another example, and in the context of FIGS. 8A-8E, another sequence may include forming the legged support structure 145 prior to placing one or more of the dies 115-1 through 115-5.

As described in connection with FIGS. 1A-8E, and elsewhere herein, a series of operations may be performed to form an apparatus including a legged support structure to mitigate stacked die overhang deflection. The series of operations may include, for example, forming a legged support structure (e.g., the legged support structure 145 of FIG. 8B) on a substrate (e.g., the substrate 110) and placing a first semiconductor die (e.g., the die 115-4 of FIG. 8C) above the substrate and proximate to the legged support structure. The series of operations may include placing a second semiconductor die (e.g., the die 115-5 of FIG. 8C) above the first semiconductor die to achieve a stacked arrangement of the second semiconductor die above the first semiconductor die in which at least a portion of the legged support structure is below an overhang portion (e.g., the overhang portion 150 of FIG. 8C), of the second semiconductor die, that extends beyond an edge of the first semiconductor die.

Additionally, or alternatively, the series of operations may include attaching an end of a ductile cable to a substrate (e.g., the substrate 110 of FIG. 8B) and forming, from the ductile cable, a legged support structure (e.g., the legged support structure 145 of FIG. 8B) along an approximately linear path having a side-profile that includes a support region (e.g., the approximately horizontal span 160 of FIG. 1B). The series of operations may include placing a first semiconductor die (e.g., the die 115-4 of FIG. 8C) proximate to the legged support structure and placing a second semiconductor die (e.g., the die 115-5) above the first semiconductor die to achieve a stacked arrangement of the second semiconductor die above the first semiconductor die in which the support region is directly below an overhang portion (e.g., the overhang portion 150 of FIG. 8C), of the second semiconductor die, that extends beyond an edge of the first semiconductor die.

As indicated herein, FIGS. 8A-8E are provided as an example. Other examples may differ from what is described with regard to FIGS. 8A-8E.

Implementations described in connection with FIGS. 1A-8E may include a semiconductor die package (e.g., the apparatus 100) including a stacked die arrangement. The semiconductor die package includes one or more legged support structures (e.g., implementations of the legged support structure 145) between respective overhang portions (e.g., implementations of the overhang portion 150) of the stacked die arrangement and a substrate (e.g., the substrate 110) of the semiconductor die package. The one or more legged support structures may reduce a likelihood of the respective overhang portions deflecting during manufacturing of the semiconductor die package. By reducing the likelihood of the overhang portions deflecting during the manufacturing of the semiconductor die package, a quality and reliability of the semiconductor die package may be increased relative to a quality and reliability of another semiconductor die package (e.g., including another stacked die arrangement) not including the legged support structures.

In this way, an amount of resources (e.g., semiconductor manufacturing tools, manpower, computing resources, and/or raw materials) needed to support a market of the semiconductor die package may be decreased. Such resources may accordingly, be reallocated to other semiconductor die package manufacturing needs.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

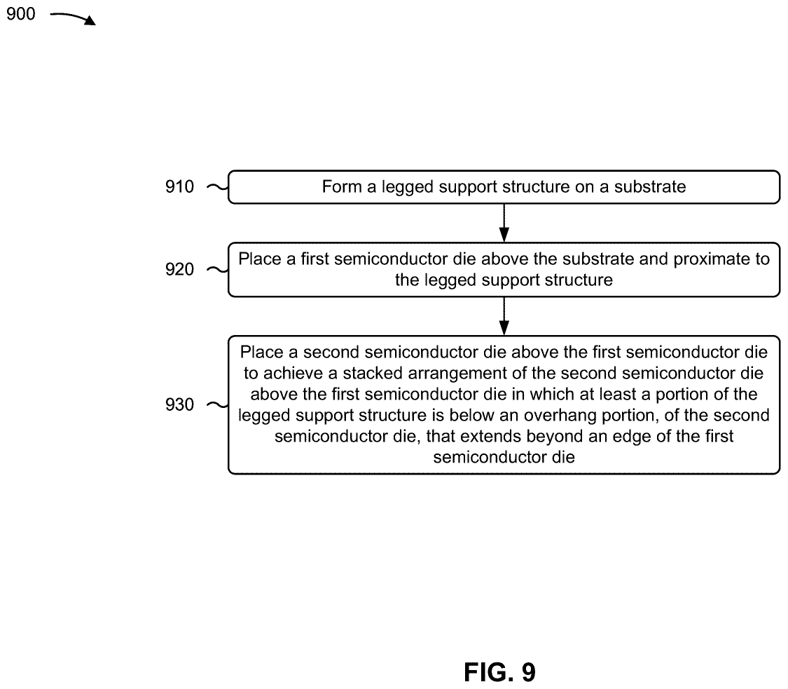

FIG. 9 is a flowchart of an example method 900 associated with legged support structure to mitigate stacked die overhang deflection. In some implementations, one or more process blocks of FIG. 9 may be performed by various semiconductor manufacturing equipment.

As shown in FIG. 9, the method 900 may include forming a legged support structure on a substrate (block 910). As further shown in FIG. 9, the method 900 may include placing a first semiconductor die above the substrate and proximate to the legged support structure (block 920). As further shown in FIG. 9, the method 900 may include placing a second semiconductor die above the first semiconductor die to achieve a stacked arrangement of the second semiconductor die above the first semiconductor die in which at least a portion of the legged support structure 145 is below an overhang portion 150, of the second semiconductor die, that extends beyond an edge of the first semiconductor die (block 930).

The method 900 may include additional aspects, such as any single aspect or any combination of aspects described below and/or described in connection with one or more other methods or operations described elsewhere herein.

In a first aspect, forming the legged support structure comprises forming the legged support structure from a ductile material, wherein the ductile material has a tensile strength that is included in a range of approximately 200 Newtons per square millimeter to approximately 380 Newtons per square millimeter.

In a second aspect, alone or in combination with the first aspect, forming the legged support structure comprises forming the legged support structure from a ductile material, wherein the ductile material has an elongation at break property that is included in a range of approximately 10% to approximately 20%.

In a third aspect, alone or in combination with one or more of the first and second aspects, forming the legged support structure comprises forming the legged support structure using a wire bond tool.

In a fourth aspect, alone or in combination with one or more of the first through third aspects, forming the legged support structure comprises forming the legged support structure along a path that is approximately parallel to the edge of the first semiconductor die.

In a fifth aspect, alone or in combination with one or more of the first through fourth aspects, forming the legged support structure comprises forming the legged support structure along a path that is approximately orthogonal to the edge of the first semiconductor die.

Although FIG. 9 shows example blocks of a method 900, in some implementations, the method 900 may include additional blocks, fewer blocks, different blocks, or differently arranged blocks than those depicted in FIG. 9. Additionally, or alternatively, two or more of the blocks of the method 900 may be performed in parallel. The method 900 is an example of one method that may be performed by one or more devices described herein. These one or more devices may perform or may be configured to perform one or more other methods based on operations described herein.

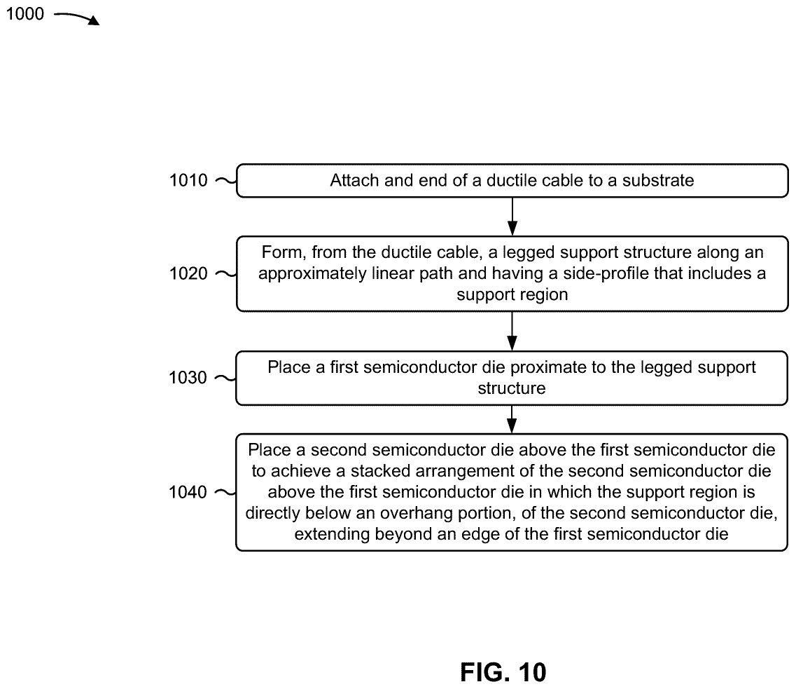

FIG. 10 is a flowchart of an example method 1000 associated a with legged support structure to mitigate stacked die overhang deflection. In some implementations, one or more process blocks of FIG. 10 may be performed by various semiconductor manufacturing equipment.

As shown in FIG. 10, the method 1000 may include attaching an end of a ductile cable to a substrate (block 1010). As further shown in FIG. 10, the method 1000 may include forming, from the ductile cable, a legged support structure along an approximately linear path and having a side-profile that includes a support region (block 1020). As further shown in FIG. 10, the method 1000 may include placing a first semiconductor die proximate to the legged support structure (block 1030). As further shown in FIG. 10, the method 1000 may include placing a second semiconductor die above the first semiconductor die to achieve a stacked arrangement of the second semiconductor die above the first semiconductor die in which the support region is directly below an overhang portion, of the second semiconductor die, extending beyond an edge of the first semiconductor die (block 1040).

The method 1000 may include additional aspects, such as any single aspect or any combination of aspects described below and/or described in connection with one or more other methods or operations described elsewhere herein.

In a first aspect, attaching the end of the ductile cable to the substrate comprises bonding the end of the ductile cable to a bond pad included in the substrate using a solid phase welding process.

In a second aspect, alone or in combination with the first aspect, attaching the end of the ductile cable to the substrate comprises attaching a bond wire that comprises a gold material, a silver material, a palladium material, or an aluminum material.

In a third aspect, alone or in combination with one or more of the first and second aspects, the end of the ductile cable is a first end and further comprising attaching a second end of the ductile cable to the substrate, wherein attaching the second end of the ductile cable to the substrate forms a wire loop structure including the ductile cable.

In a fourth aspect, alone or in combination with one or more of the first through third aspects, the approximately linear path is a first approximately linear path, the legged support structure is a first legged support structure, the support region is a first support region having a first height, and further comprising forming, from the ductile cable, a second legged support structure along a second approximately linear path that is parallel to the first approximately linear path, wherein forming the second legged support structure includes forming the second legged support structure to include a second support region having a second height that is greater relative to the first height, and placing a third semiconductor die above second semiconductor die to achieve a stacked arrangement of the third semiconductor die above the second semiconductor die in which the second support region is directly below an overhang portion, of the third semiconductor die, extending beyond an edge of the second semiconductor die.

In a fifth aspect, alone or in combination with one or more of the first through fourth aspects, forming the second legged support structure comprises forming the second legged support structure prior to placing the first semiconductor die.

In a sixth aspect, alone or in combination with one or more of the first through fifth aspects, forming the second legged support structure comprises forming the second legged support structure after placing the second semiconductor die.

Although FIG. 10 shows example blocks of a method 1000, in some implementations, the method 1000 may include additional blocks, fewer blocks, different blocks, or differently arranged blocks than those depicted in FIG. 10. Additionally, or alternatively, two or more of the blocks of the method 1000 may be performed in parallel. The method 1000 is an example of one method that may be performed by one or more devices described herein. These one or more devices may perform or may be configured to perform one or more other methods based on operations described herein.

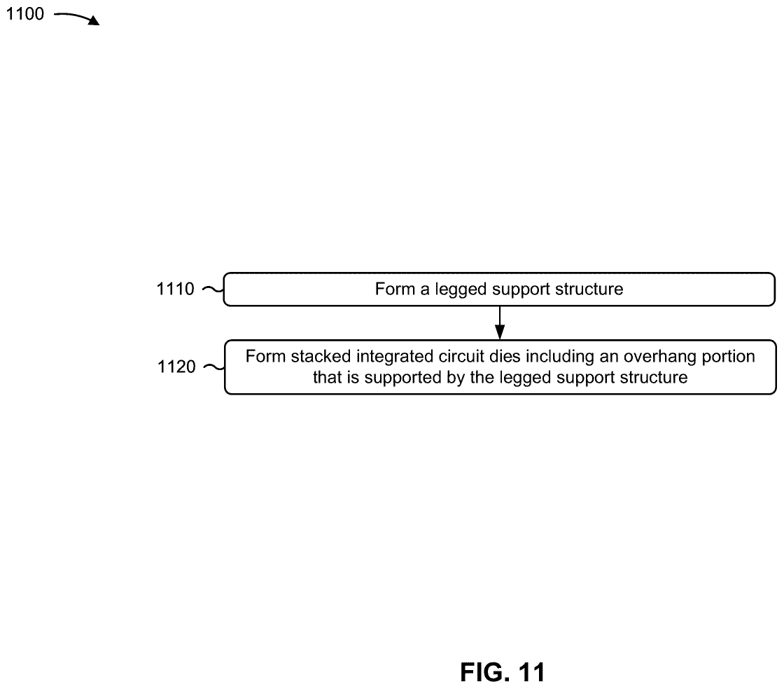

FIG. 11 is a flowchart of an example method 1100 associated with a legged support structure to mitigate stacked die overhang deflection. In some implementations, one or more process blocks of FIG. 11 may be performed by various semiconductor manufacturing equipment. In some implementations, the method 1100 may include forming an integrated assembly (e.g., the memory device of FIG. 2) that includes the stacked integrated circuit dies 225 and the legged support structure 145.

As shown in FIG. 11, the method 1100 includes forming a legged support structure (block 1110). As further shown in FIG. 11, the method 1100 includes forming stacked integrated circuit dies including an overhang portion that is supported by the legged support structure (block 1120).

Although FIG. 11 shows example blocks of a method 1100, in some implementations, the method 1100 may include additional blocks, fewer blocks, different blocks, or differently arranged blocks than those depicted in FIG. 11. Additionally, or alternatively, two or more of the blocks of the method 1100 may be performed in parallel. The method 1100 is an example of one method that may be performed by one or more devices described herein. These one or more devices may perform or may be configured to perform one or more other methods based on operations described herein.

In some implementations, a semiconductor device assembly includes a substrate; a first semiconductor die above the substrate and comprising: an edge; a second semiconductor die in a stacked arrangement above the first semiconductor die and comprising: an overhang portion extending beyond the edge; and a legged support structure between the overhang portion and the substrate and comprising: an approximately horizontal span traversing a path that is approximately parallel to the edge and directly below the overhang portion.

In some implementations, a semiconductor device assembly includes a substrate; a first semiconductor die, in a first stack of dies, above the substrate and comprising: a first edge; a second semiconductor die, in a second stack of dies, above the substrate, proximate to the first semiconductor die, and comprising: a second edge that is approximately parallel the first edge and separated from the first edge; a third semiconductor die in a stacked arrangement above the first semiconductor die in the first stack of dies and comprising: a first overhang portion extending beyond the first edge; a fourth semiconductor die in a stacked arrangement above the second semiconductor die in the second stack of dies and comprising: a second overhang portion extending beyond the second edge; and a legged support structure between the first semiconductor die and the second semiconductor die and comprising: a first portion directly under the first overhang portion and configured to support the first overhang portion; and a second portion directly under the second overhang portion and configured to support the second overhang portion.

In some implementations, a semiconductor device assembly includes a substrate; a first semiconductor die above the substrate and comprising: an edge; a second semiconductor die in a stacked arrangement above the first semiconductor die and comprising: an overhang portion extending beyond the edge; and a support structure between the overhang portion and the substrate and including a profile comprising: an approximately horizontal span directly below the overhang portion; and radially curved portions at opposing ends of the approximately horizontal span.

In some implementations, a method includes forming a legged support structure on a substrate; placing a first semiconductor die above the substrate and proximate to the legged support structure; and placing a second semiconductor die above the first semiconductor die to achieve a stacked arrangement of the second semiconductor die above the first semiconductor die in which at least a portion of the legged support structure is below an overhang portion, of the second semiconductor die, that extends beyond an edge of the first semiconductor die.

In some implementations, a method includes attaching an end of a ductile cable to a substrate; forming, from the ductile cable, a legged support structure along an approximately linear path and having a side-profile that includes a support region; placing a first semiconductor die proximate to the legged support structure; and placing a second semiconductor die above the first semiconductor die to achieve a stacked arrangement of the second semiconductor die above the first semiconductor die in which the support region is directly below an overhang portion, of the second semiconductor die, extending beyond an edge of the first semiconductor die.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” As used herein, “satisfying a threshold” may depending on the context, refer to a value being greater than the threshold, greater than or equal to the threshold, less than the threshold, less than or equal to the threshold, equal to the threshold, not equal to the threshold, or the like. All ranges described herein are inclusive of numbers at the ends of those ranges, unless specifically indicated otherwise.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a substrate;
a first semiconductor above the substrate and comprising:
an edge;
a second semiconductor die in a stacked arrangement above the first semiconductor die and comprising:
an overhang portion extending beyond the edge; and
a legged support structure between the overhang portion and the substrate and comprising:
an approximately horizontal span traversing a path that is approximately parallel to the edge and directly below the overhang portion.

2. The semiconductor device assembly of claim 1, wherein the second semiconductor die comprises:
an adhesive layer on an underside surface of the overhang portion.

3. The semiconductor device assembly of claim 2, wherein the approximately horizontal span and the adhesive layer are in contact.

4. The semiconductor device assembly of claim 1, wherein the approximately horizontal span comprises:
a cross section having an approximately trapezoidal shape.

5. The semiconductor device assembly of claim 1, wherein the approximately horizontal span comprises:
a cross section having at least one approximately linear edge.

6. The semiconductor device assembly of claim 1, wherein the approximately horizontal span comprises:
a cross section having at least one curved edge.

7. The semiconductor device assembly of claim 1, wherein the substrate comprises:
a bond pad, and
wherein a leg) of the legged support structure is bonded to the bond pad.

8. The semiconductor device assembly of claim 1, wherein the legged support structure comprises:
a wire loop structure.

9. The semiconductor device assembly of claim 1, wherein the legged support structure comprises:
a copper material.

10. The semiconductor device assembly of claim 1, wherein the legged support structure comprises:
a material having a modulus of elasticity that is included in a range of approximately 115 gigapascal to approximately 130 gigapascal.

11. The semiconductor device assembly of claim 1, wherein a cross-section of the approximately horizontal span comprises:
a width that is included in a range of approximately 30 microns to approximately 38 microns.

12. The semiconductor device assembly of claim 1, wherein the first semiconductor die comprises:
a first memory device, and
wherein the second semiconductor die comprises:
a second memory device.

13. A semiconductor device assembly, comprising:
a substrate;
a first semiconductor die, in a first stack of dies, above the substrate and comprising:
a first edge;
a second semiconductor die, in a second stack of dies, above the substrate, proximate to the first semiconductor die, and comprising:
a second edge that is approximately parallel the first edge and separated from the first edge;
a third semiconductor die in a stacked arrangement above the first semiconductor die in the first stack of dies and comprising:
a first overhang portion extending beyond the first edge;
a fourth semiconductor die in a stacked arrangement above the second semiconductor die in the second stack of dies and comprising:
a second overhang portion extending beyond the second edge; and
a legged support structure between the first semiconductor die and the second semiconductor die and comprising:
a first portion directly under the first overhang portion and configured to support the first overhang portion; and
a second portion directly under the second overhang portion and configured to support the second overhang portion.

14. The semiconductor device assembly of claim 13, wherein at least one of the first semiconductor die, the second semiconductor die, the third semiconductor die, or fourth semiconductor die comprises:
a NAND memory device.

15. The semiconductor device assembly of claim 13, wherein at least one of the first semiconductor die, the second semiconductor die, the third semiconductor die, or the fourth semiconductor die comprises:
a dynamic random access memory device.

16. The semiconductor device assembly of claim 13, wherein at least one of the first semiconductor die, the second semiconductor die, the third semiconductor die, or the fourth semiconductor die has a thickness that is included in a range of approximately 40 microns to approximately 50 microns.

17. The semiconductor device assembly of claim 13, further comprising:
a fifth semiconductor die below an approximately horizontal span of the legged support structure.

18. The semiconductor device assembly of claim 17, wherein the substrate comprises:
a bond pad between the fifth semiconductor die and the first semiconductor die, and
wherein a leg of the legged support structure is connected to the bond pad.

19. The semiconductor device assembly of claim 17, wherein the fifth semiconductor die comprises:
a controller device.

20. A semiconductor device assembly, comprising:
a substrate;
a first semiconductor die above the substrate and comprising:
an edge;
a second semiconductor die in a stacked arrangement above the first semiconductor die and comprising:
an overhang portion extending beyond the edge; and
a support structure between the overhang portion and the substrate and including a profile comprising:
an approximately horizontal span directly below the overhang portion; and
radially curved portions at opposing ends of the approximately horizontal span.

21. The support structure of claim 20, further comprising:
legged support structures extending from the radially curved portions to bond pads below the overhang portion.

22. The semiconductor device assembly of claim 20, wherein the substrate comprises:
a thermal via structure, and
wherein a legged support structure of the support structure connects to the thermal via structure.

23. A method, comprising:
forming a legged support structure on a substrate;
placing a first semiconductor die above the substrate and proximate to the legged support structure; and
placing a second semiconductor die above the first semiconductor die to achieve a stacked arrangement of the second semiconductor die above the first semiconductor die in which at least a portion of the legged support structure is below an overhang portion, of the second semiconductor die, that extends beyond an edge of the first semiconductor die.

24. The method of claim 23, wherein forming the legged support structure comprises:
forming the legged support structure from a ductile material,
wherein the ductile material has a tensile strength that is included in a range of approximately 200 Newtons per square millimeter to approximately 380 Newtons per square millimeter.

25. The method of claim 23, wherein forming the legged support structure comprises:
forming the legged support structure from a ductile material,
wherein the ductile material has an elongation at break property that is included in a range of approximately 10% to approximately 20%.

26. The method of claim 23, wherein forming the legged support structure comprises:
forming the legged support structure using a wire bond tool.

27. The method of claim 23, wherein forming the legged support structure comprises:
forming the legged support structure along a path that is approximately parallel to the edge of the first semiconductor die.

28. The method of claim 23, wherein forming the legged support structure comprises:
forming the legged support structure along a path that is approximately orthogonal to the edge of the first semiconductor die.

29. A method, comprising:
attaching and end of a ductile cable to a substrate;
forming, from the ductile cable, a legged support structure along an approximately linear path and having a side-profile that includes a support region;
placing a first semiconductor die proximate to the legged support structure; and
placing a second semiconductor die above the first semiconductor die to achieve a stacked arrangement of the second semiconductor die above the first semiconductor die in which the support region is directly below an overhang portion, of the second semiconductor die, extending beyond an edge of the first semiconductor die.

30. The method of claim 29, wherein attaching the end of the ductile cable to the substrate comprises:
bonding the end of the ductile cable to a bond pad included in the substrate using a solid phase welding process.

31. The method of claim 29, wherein attaching the end of the ductile cable to the substrate comprises:
attaching a bond wire that comprises:
a gold material,
a silver material,
a palladium material, or
an aluminum material.

32. The method of claim 29, where the end of the ductile cable is a first end and further comprising:
attaching a second end of the ductile cable to the substrate,
wherein attaching the second end of the ductile cable to the substrate forms a wire loop structure including the ductile cable.

33. The method of claim 29, wherein the approximately linear path is a first approximately linear path, the legged support structure is a first legged support structure, the support region is a first support region having a first height, and further comprising:
forming, from the ductile cable, a second legged support structure along a second approximately linear path that is parallel to the first approximately linear path,
wherein forming the second legged support structure includes forming the second legged support structure to include a second support region having a second height that is greater relative to the first height, and
placing a third semiconductor die above second semiconductor die to achieve a stacked arrangement of the third semiconductor die above the second semiconductor die in which the second support region is directly below an overhang portion, of the third semiconductor die, extending beyond an edge of the second semiconductor die.

34. The method of claim 33, wherein forming the second legged support structure comprises:
forming the second legged support structure prior to placing the first semiconductor die.

35. The method of claim 33, wherein forming the second legged support structure comprises:
forming the second legged support structure after placing the second semiconductor die.
